(19) United States
(12) Patent Application Publication
(10) Pub. No.: US 2009/0039341 A1
(43) Pub. Date: Feb. 12, 2009

(54) Method for the Manufacturing of a Non-Volatile Ferroelectric Memory Device and Memory Device Thus Obtained

(76) Inventors: Albert W. Marsman, Eindhoven (NL); Dagobert Michel De Leeuw, Eindhoven (NL); Gerwin Hermanus Gelinck, Eindhoven (NL)

Correspondence Address: PHILIPS INTELLECTUAL PROPERTY & STANDARDS, PO BOX 3001, BRIARCLIFF MANOR, NY, 10510-8001, US

(21) Appl. No.: 10/584,041

(22) PCT Filed: Nov. 29, 2004
(86) PCT No.: PCT/IB04/52580

§ 371 Date: Jun. 21, 2006

(30) Foreign Application Priority Data
Dec. 22, 2003 (EP) 03104887.9

(51) Int. Cl. H01L 27/115; H01L 51/00; H01L 21/8246

(52) U.S. Cl. 257/40; 257/295; 438/3; 257/E27.104; 257/E21.663; 257/E51.001

(57) ABSTRACT

The present invention relates to non-volatile ferroelectric memory devices (30) comprising a transistor (22) and a capacitor (23), and more particularly to non-volatile electrically erasable programmable ferroelectric memory elements, and a method for processing such non-volatile ferroelectric memory devices (30). The method according to the invention comprises a limited number of mask steps because a gate dielectric layer of the transistor (22) and a dielectric layer of the capacitor (23) are made from the same organic or inorganic ferroelectric layer (14).

The present invention relates to non-volatile ferroelectric memory devices and more particularly to non-volatile electrically erasable programmable ferroelectric memory elements for polymeric integrated circuits, and methods for manufacturing and operating such non-volatile ferroelectric memory devices.

Memory technologies can be broadly divided into two categories: volatile and non-volatile memories. Volatile memories, such as SRAM (Static Random Access Memory) and DRAM (Dynamic Random Access Memory), lose their contents when power is removed while non-volatile memories, which are based on ROM (Read Only Memory) technology do not. DRAM, SRAM and other semiconductor memories are widely used for the processing and high-speed storage of information in computers and other devices. In recent years EEPROMs and Flash Memory have been introduced as non-volatile memories that store data as electrical charges in floating-gate electrodes. Non-volatile memories (NVMs) are used in a wide variety of commercial and military electronic devices and equipment, such as e.g. hand-held telephones, radios and digital cameras. The market for these electronic devices continues to demand devices with a lower voltage, lower power consumption and a decreased chip size. EEPROMs and Flash Memory, however, take long time to write data, and have limits on the number of times that data can be rewritten.

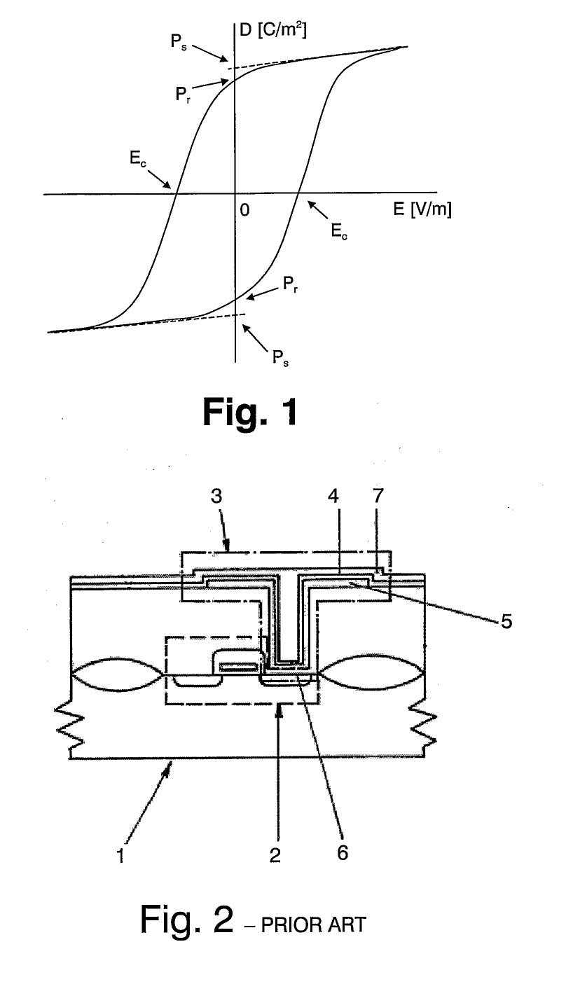

As a way to avoid the shortcomings of the types of memory described above, ferroelectric random access memories (FRAMs), which store data by the electrical polarization of a ferroelectric film, were suggested. A ferroelectric memory cell comprises a ferroelectric capacitor and a transistor. Its construction is similar to the storage cell of a DRAM. The difference is in the dielectric properties of the material between the capacitor's electrodes, which in case of a FRAM is a ferroelectric material. A material is said to be ferroelectric when it features a permanent electric dipole moment, i.e. even without application of an external electric field. In this case, there is more than one stable electric polarization state within the unit cell of its lattice structure. This results in a permittivity of the material being a non-linear function of an applied electric field (E). A plot of the surface-charge density D versus applied field E on a capacitor produces a characteristic hysteresis loop, as is shown schematically in FIG. 1. The positive and negative saturation polarizations (Pₛ) correspond to the binary logic states, e.g. “1” and “0”, of a memory cell, whereas the remnant polarizations (Pᵣ) correspond to the state the cell resides in when the voltage of the power source, or thus the electrical field E, is turned off. Hence, the remnant polarization provides the non-volatility of the memory cell. Because applying the electric field E of an FRAM controls the electrical polarization of a ferroelectric capacitor, compared to writing by injecting hot electrons or using the tunnel effect, as is done on EEPROM and Flash Memory devices, the writing speed is faster by 1,000 times or more. Also, much less power is required for writing, only between 1/1000 and 1/100000 of the amount of power for programming EEPROM of Flash Memory devices. Furthermore, eliminating the need to use tunnel oxidized film extends the life of an FRAM, allowing 100,000 times more write cycles than that of Flash Memory or EEPROM devices.

The ferroelectric film on the memory cell capacitor may be made of inorganic materials such barium titanate (BaTiO₃), lead zirconate titanate (PZT-Pb(Zr, Ti)O₃)), PLZT ((Pb,La)(Zr,Ti)O₃)) or SBT (SrBi₂Ta₂O₉), or of organic molecular materials such as triglycine sulphate (TGS) or organic polymers with polar groups such as e.g. polyvinylidenedifluoride (P(VDF)), odd numbered nylons or polyvinylidene cyanide (PVCN). Optimization of these polar layers may be done by the use of (random) copolymers of for example P(VDF) with trifluorethylene (TrFE) or tetrafluoroethylene (TeFE). In general any material that has a crystalline phase with a crystal structure belonging to an asymmetric space group can be used as long as the electrical breakdown field is higher than the required switching field (related to coercive field). However, in case of ferroelectric liquid crystal polymers for example, which are being used for, for example, display purposes, the remnant polarization Pᵣ is generally low (˜5-10 mC/m²), being dependent on a dipole moment from a large molecule. This may be too low for memory applications. In addition, operating conditions will be very temperature sensitive due to the liquid crystal properties, such as their phase transitions. For memory applications one likes to have stable properties at temperatures in between approximately −20 to 150° C. Therefore, in case of non-volatile memory cells used in polymeric integrated circuits, organic ferroelectric materials, for example as mentioned above, are preferably used as a ferroelectric layer, because they show a high remnant polarization.

In WO 98/14989 a memory cell 1 is described comprising a transistor 2 connected a storage capacitor 3 (see FIG. 2). The storage capacitor 3 contains a polymer storage dielectric 4 having particular ferroelectric properties. The polymer storage dielectric 4 may for example be nylon 11, nylon 9, nylon 7, nylon 5 or polyvinylidene with fluorine atoms such as P(VDF) or its copolymer with trifluorethylene (TrFE). A first electrode 5 of the capacitor 3 is conductively connected with a first connection 6 of the transistor 2. The polymer storage dielectric 4 is positioned on top of the first electrode 5 of the capacitor 3 and covered with a second electrode 7. Both first electrode 5 and second electrode 7 as well as the polymer storage dielectric 4 are deposited onto the transistor 2 in different steps, by which metallization of the transistor 2 structure mainly leads to formation of the respective capacitor 3.

A disadvantage of the device in WO 98/14989 is that in order to form devices which comprise a transistor 2 and a storage capacitor 3 with a ferroelectric material as a polymer storage dielectric 4, many mask steps are required, as a result of which production time increases. This makes the manufacturing of such ferroelectric memory devices rather costly.

It is an object of the present invention to provide a cheap and fast fabrication method for fabricating ferroelectric non-volatile, electrically re-programmable memory devices as well as a memory device made in accordance with the method.

The above objective is accomplished by a method and device according to the present invention.

The present invention provides a device applicable for non-volatile memory purposes, or latch-up circuits. The device, according to the present invention, comprises
a selection device having a control electrode and a first dielectric layer insulating the control electrode from the rest of the selection device, and
a storage device comprising a second dielectric layer, wherein the first dielectric layer of the selection device and the second dielectric layer of the storage device are individual parts of one and the same ferroelectric layer.

In one embodiment, the device may be a transistor, comprising a gate electrode, a gate dielectric and a drain and a source and the storage device may be a capacitor, comprising a first electrode, a dielectric layer and a second electrode, wherein the gate dielectric of the transistor and the dielectric layer of the capacitor may be may be individual parts of one and the same ferroelectric layer. The transistor may for example be a thin film transistor.

In an embodiment of the invention, the ferroelectric layer may for example be an inorganic ferroelectric layer. In another embodiment, the ferroelectric layer may be an organic ferroelectric layer, such as for example a ferroelectric oligomer or polymer layer, which may for example be selected from (CH₂—CF₂)ₙ, (CHF—CF₂), (CF₂—CF₂)ₙ or combinations thereof, to form (random) copolymers like: (CH₂—CF₂)ₙ—(CHF—CF₂)ₘ or (CH₂—CF₂)ₙ—(CF₂—CF₂)ₘ. Furthermore, the ferroelectric layer may comprise inorganics dispersed within organics (e.g. matrix) or vice versa.

In the device, according to the present invention, the gate electrode of the transistor and the first electrode of the capacitor may be individual parts of a first conductive layer, e.g. a conductive polymer layer.

In another embodiment, the drain and source of the transistor and the second electrode of the capacitor may be individual parts of a second conductive layer, e.g. a second conductive polymer layer.

One of the first and second electrode of the capacitor may electrically be connected to either the gate, the source or the drain of the transistor.

In an embodiment of the present invention, the gate electrode, the drain and the source of the transistor and the first electrode and the second electrode of the capacitor may be formed of the same material, which may for example be PEDOT/PSS, but may also be any other suitable conductive material.

The device of the present invention may furthermore comprise a semiconductive layer, which may for example be an organic or an inorganic semiconductor. In a preferred embodiment, the semiconductive layer may be an organic semiconductive layer. The advantage of using an organic semiconductor is that the interface between the semiconductive layer and the ferroelectric layer show very good properties. In a specific embodiment, the semiconductive layer may comprise a pentacene semiconductive layer.

The present invention furthermore provides a method for processing a device applicable for non-volatile memory purposes, or latch-up circuits comprising a selection device comprising a control electrode, a first dielectric layer and a first and second main electrode, and a storage device comprising a first electrode, a second dielectric layer and a second electrode. The method of the present invention comprises:
providing and patterning of a first conductive layer onto a substrate, thus forming the first electrode of the storage device and the control electrode of the selection device,
providing and patterning of a ferroelectric layer on the patterned first conductive layer, thus forming the first dielectric layer of the selection device and the second dielectric layer of the storage device, and
providing and patterning of a second conductive layer on the patterned ferroelectric layer, thus forming the second electrode of the capacitor and the first and second main electrode of the selection device.

The method of the present invention may furthermore comprise providing of a semiconductive layer onto the patterned second conductive layer. The semiconductive layer may for example be an inorganic or an organic semiconductor. In a preferred embodiment, the semiconductive layer may be an organic semiconductive layer such as for example a pentacene semiconductive layer.

In one embodiment, patterning of the first conductive layer and/or the second conductive layer may be done by means of standard photolithography.

Providing of the ferroelectric layer may comprise providing of an inorganic or an organic ferroelectric layer. In one embodiment, providing of a ferroelectric layer may be providing of a ferroelectric polymer layer which may be selected from (CH₂—CF₂)ₙ, (CHF—CF₂)ₙ (CF₂—CF₂)ₙ or combinations thereof, to form (random) copolymers like: (CH₂—CF₂)ₙ—(CHF—CF₂)ₘ or (CH₂—CF₂)ₙ—(CF₂—CF₂)ₘ. Patterning of the ferroelectric layer may be done by for example crosslinking the ferroelectric layer.

In an embodiment of the present invention, providing of the first and/or conductive layer may be providing any of a metal layer or a conductive polymer layer. In a specific embodiment, providing of the first and/or conductive layer may be providing of a PEDOT/PSS layer.

An advantage of the method described in the present invention is that because only a few mask steps are required, processing time and consequently processing costs are reduced.

These and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

FIG. 1 shows surface charge density D on a ferroelectric capacitor versus applied electric field E.

FIG. 2 shows a cross-section of a memory cell comprising a transistor and a capacitor with a ferroelectric dielectric layer according to the prior art.

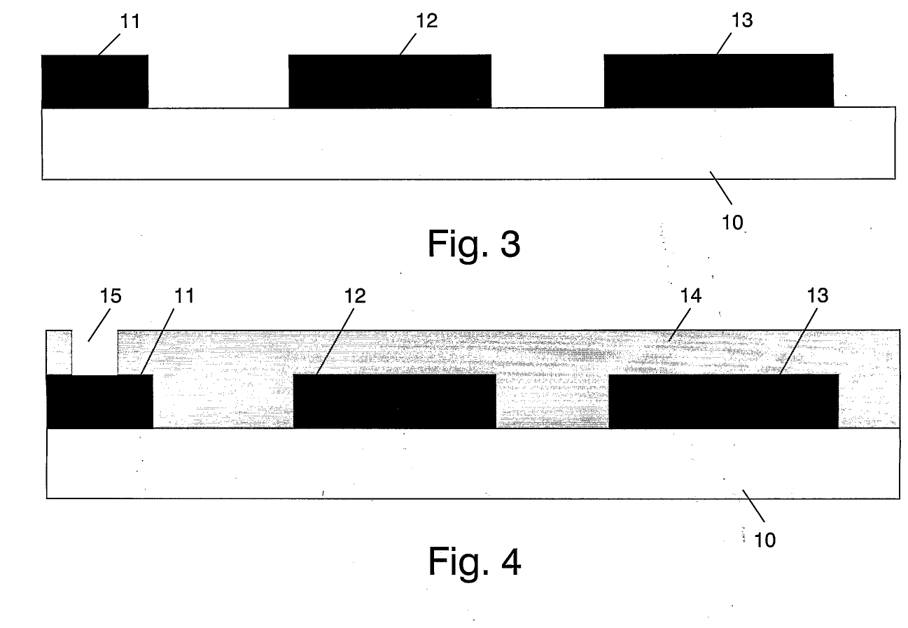

FIG. 3-7 show cross sectional views of the successive stages in the manufacture of a 1T/1C memory cell according to an embodiment of the present invention.

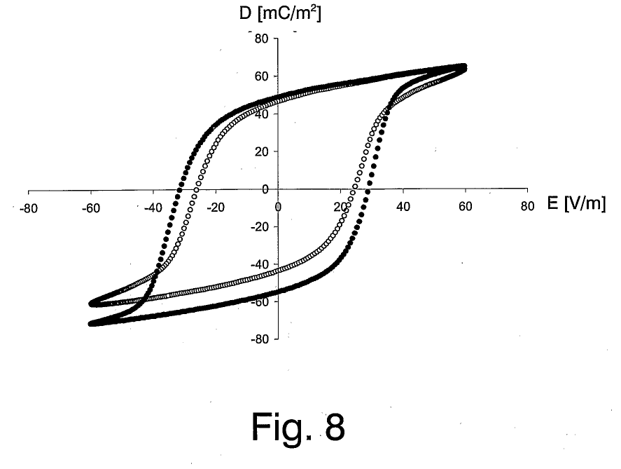

FIG. 8 shows the ferroelectric hysteresis loop of a PEDOT/PSS-VDF/TrFE-PEDOT/PSS stack before (open circles) and after (closed circles) annealing.

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. Where the term “comprising” is used in the present description and claims, it does not exclude other elements or steps. Where an indefinite or definite article is used when referring to a singular noun e.g. “a” or “an”, “the”, this includes a plural of that noun unless something else is specifically stated.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

In FIG. 3 to 7 the different steps in the manufacturing of a 1T/1C memory device 30, comprising one switching element e.g. transistor 22 and one storage element e.g. capacitor 23, according to an embodiment of the present invention are illustrated.

A first step in the processing of the 1T/1C memory device 30 is illustrated in FIG. 3. A substrate 10 is provided. In embodiments of the present invention, the term “substrate” may include any underlying material or materials that may be used, or upon which a device, a circuit or an epitaxial layer may be formed. In other alternative embodiments, this “substrate” may include a semiconductor substrate such as e.g. a doped silicon, a gallium arsenide (GaAs), a gallium arsenide phosphide (GaAsP), an indium phosphide (InP), a germanium (Ge), or a silicon germanium (SiGe) substrate. The “substrate” may include for example, an insulating layer such as a SiO₂ or an Si₃N₄ layer in addition to a semiconductor substrate portion. Thus, the term substrate also includes silicon-on-glass, silicon-on sapphire substrates. The term “substrate” is thus used to define generally the elements for layers that underlie a layer or portions of interest. Also, the “substrate” may be any other base on which a layer is formed, for example a glass or metal layer.

Processing may start with an optional planarization of the substrate 10. This may be done e.g. by depositing a planarization layer of photoresist, which may for example be an epoxy- or novolac-based polymer, onto the substrate 10.

After planarization of the substrate 10 a first conductive layer is deposited onto the substrate 10. This first conductive layer may be, for example, a metal layer such as gold, aluminium, or may be an inorganic conductive layer such as an indium tin oxide (ITO) layer. Alternatively, the first conductive layer may be a conductive polymer layer, e.g. polyaniline doped with camphor sulfonic acid (PANI/CSA), or poly(3,4-etylenedioxythiophene) doped with poly(4-styrenesulfonat) (PEDOT/PSS). The thickness of the first conductive layer depends on the material that is used and on the resistance that is required. The conductive layer may have a thickness of for example 100 nm in case the first conductive layer is for example a PEDOT/PSS layer and may be 50 nm if the conductive layer is a gold layer. The first conductive layer may be deposited onto the substrate 10 by means of any suitable deposition technique such as for example sputter deposition, or in case of a conductive polymer layer, by means of, for example, spin coating.

To form a first interconnect line 11, a first electrode 12 of the capacitor 23 to be formed and a gate electrode 13 of a transistor 22 to be formed, subsequent structuring or patterning of the first conductive layer is performed, for example by means of standard photolithography. The photolithography process comprises the following subsequent steps. First, a photoresist layer is applied on top of the first conductive layer on the substrate 10, e.g. by means of spincoating. The photoresist layer may for example have a thickness of a few μm and may be made of any suitable polymer that can be used as a photoresist, such as for example poly(vinyl cinnamate) or novolak-based polymers. Thereafter, a mask is applied to align a pattern onto the substrate 10. The photoresist layer is then illuminated through the mask e.g. by means of UV light. After illumination the photoresist is developed by which either the illuminated parts of the photoresist (positive resist) or the non-illuminated parts of the photoresist (negative resist) are removed, depending on which type of photoresist has been used. Patterning of the first conductive layer is then performed using the developed photoresist layer as a mask, after which the remaining parts of the photoresist layer are removed, typically by using an organic solvent. The result is shown in FIG. 3.

In a subsequent fabrication step, which is illustrated in FIG. 4, a ferroelectric layer 14, which may be a ferroelectric organic layer or a ferroelectric inorganic layer and which may for example have a thickness of 500 nm or lower, is deposited onto the substrate 10. The organic ferroelectric layer 14 may have a thickness of for example 2000 nm or lower. If organic, the ferroelectric layer thickness preferably is in between 30 and 500 nm. The ferroelectric layer 14 may for example be a ferroelectric polymer layer based on random copolymers of vinylidenedifluoride (VDF) with trifluoroethylene (TrFE) or with chlorotrifluoroethylene which may be spincoated from for example 2-butanone Other ferroelectric polymers may also be used such as for example odd-numbered nylons, cyanopolymers polyacrylonitriles, poly(vinylidenecyanides)s and the polymers with a cyano group in the side chain, polyureas, polythioureas and polyurethanes. All polymers may be used in pure form or diluted within another polymer matrix. Ferroelectric materials are discussed in “Principles and Applications of Ferroelectrics and related materials”, M. E. Lines and A. M. Glass, Oxford Press, 2001 and in “Ferroelectric polymers, chemistry, physics and applications”, edited by Hari Singh Nalwa, Marcel Dekker, Inc 1995. For a general list of ferroelectric materials see the Landolt-Boernstein series, Springer-Verlag Heidelberg Group III; Condensed Matter; Volume 16: Ferroelectrics and related substances (1982) and Volume 36: Ferroelectrics and related substances (2002). However, for memory applications it is important that the remnant polarization Pᵣ of the ferroelectric polymer is as high as possible. Hence, materials having a high density of large dipole groups are preferred such as is the case in fluorine containing polymers, which have a remnant polarization >10 mC/m², for example ˜100 mC/m². The upper limit may be determined by the exact application. For example, an 1T-1C (one transistor, one capacitor) device preferably uses material with the highest Pᵣ possible in order to generate sufficient charge during the destructive reading.

Another important reason for Pᵣ not to be too low is that the stability of the stored states (polarizations) will be at least partly dependent on it. In this respect also the coercive field is important. A too high E_{c} results in high switching voltages (generally 2×E_{c}×layer thickness for polarization saturation). However, a too low E_{c} may result in manifestation of detrimental polarization fields within the capacitors when connected to other circuitry having parasitic capacitance.

Thus, although other polymers or molecules exist, the fluorine containing materials seem to have the most beneficial properties. The fluorinated polymer may preferably be a main chain polymer. However, the fluorinated polymer may also be a block copolymer or a side chain polymer. The fluorinated polymer may for example be (CH₂—CF₂)ₙ, (CHF—CF₂), (CF₂—CF₂)i or combinations thereof to form (random) copolymers such as for example: (CH₂—CF₂)ₙ—(CHF—CF₂)ₘ or (CH₂—CF₂)ₙ—(CF₂—CF₂)ₘ.

The ferroelectric layer 14 is patterned to form contact holes 15 to the first conductive layer where necessary. If possible, and this depends on the kind of material used for the ferroelectric layer 14, the patterning may be carried out by means of standard photolithography as described in case of patterning of the first conductive layer.

However, in case fluorinated polymers are used for the ferroelectric layer 14, application of normal photolithography for patterning is difficult, because a fluorinated polymer dissolves in the polar organic solvents commonly used to remove the photoresist, which results in a complete lift off of all layers on top. In this case, the ferroelectric polymer layer 14 may yet be patterned by means of photolithography by addition of a photosensitive cross linker, which may for example be an azide such as e.g. bisazide, to the fluorinated polymer spincoat solution. After spincoating of the ferroelectric polymer layer 14 with the cross linker, the ferroelectric layer 14 is irradiated with UV light through a mask which leads to a partially non-soluble layer. Non-solubility of the ferroelectric polymer layer 14 is accomplished by means of crosslinking of the polymer. The parts of the ferroelectric polymer layer 14 which are not illuminated, and which thus do not cross-link, may be subsequently removed by washing with for example acetone leaving a patterned film that may be annealed to increase the ferroelectric properties of the layer 14. The crosslinking does not substantially alter the ferroelectric switching behavior whereas it greatly improves stack integrity, because upon further processing the cross linked ferroelectric polymer layer 14 will not dissolve. All crosslinking materials may be used, on one condition that they do not disintegrate into charged particles during exposure. Examples are known where peroxides or bis-amines are used to cross-link. These however result in charged side products, which is detrimental for both the memory characteristics of the switching capacitor and the transistor. The result after patterning of the ferroelectric layer 14 is illustrated in FIG. 4. The ferroelectric layer 14 will later on, when the device is ready and in use, act both as gate dielectric in the active transistor 22 and as switching layer between first electrode 12 and second electrode 18 of the capacitor 23.

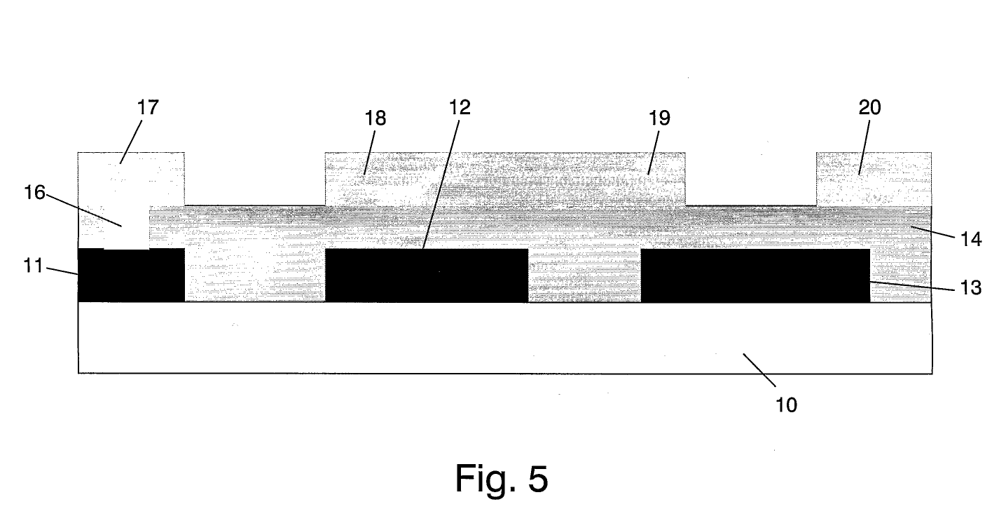

After patterning the ferroelectric layer 14, a second conductive layer is deposited on top of the patterned ferroelectric layer 14. The second conductive layer also fills the contact holes 15 formed in the ferroelectric layer 14, thus forming a vertical interconnect 16. This is illustrated in FIG. 5. The second conductive layer may for example be a metal layer e.g. gold, aluminium, or indium tin oxide (ITO), or another conductive polymer layer e.g. polyaniline doped with camphor sulfonic acid (PANI/CSA) or poly(3,4-etylenedioxythiophene) doped with poly(4-styrenesulfonate) (PEDOT/PSS)) and may have a thickness which is comparable to the thickness of the first conductive layer and which is also dependent on the material used and on the resistance or circuit speed that is required. The thickness of the second conductive layer may for example be 50 nm in case of gold or 100 nm in case of PEDOT/PSS. The material of which the first and second conductive layers are formed should be such that it is possible to construct low-ohmic vertical interconnects 16.

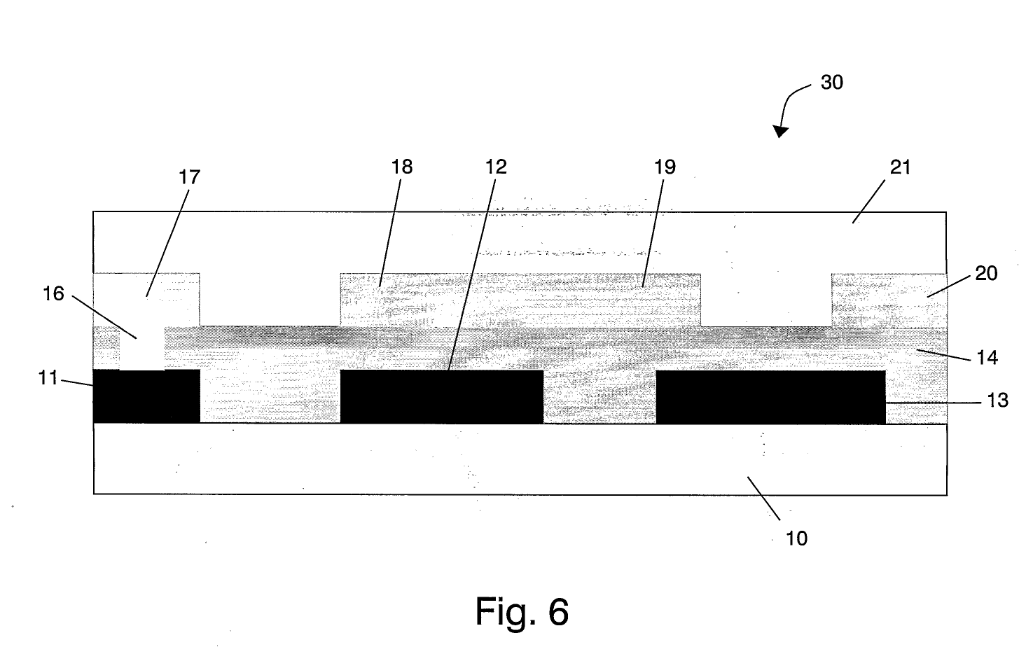

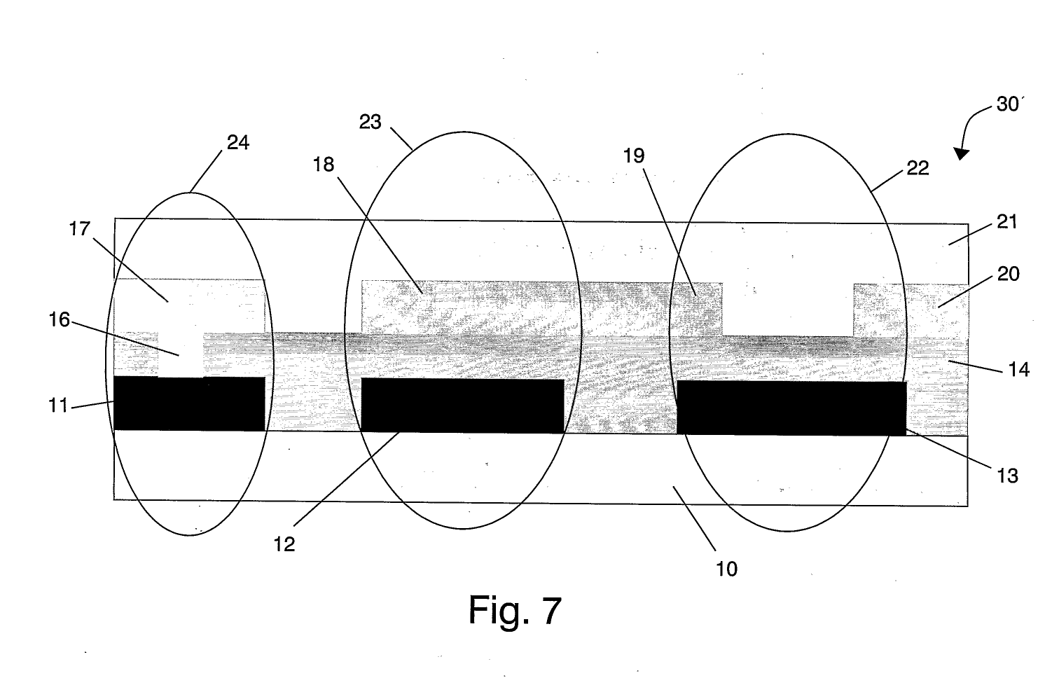

To form a second interconnect line 17, a second electrode 18 of the capacitor 23, a drain region 19 and source region 20, the second conductive layer is patterned. Again, this may be done by means of standard photolithography as explained above with respect to patterning of the first conductive layer. The photoresist used during this patterning may be any suitable polymer such as for example poly(vinyl cinnamate) or novolak-based polymers. Furthermore, patterning may also be performed using non-lithographic techniques known in the art, such as for example inkjet or silk screen printing in case of soluble conducting polymers, or for example microcontact printing in case of e.g. gold or for example microembossing in case of ITO. A semiconductive layer 21 is then applied on top of the patterned second conductive layer (FIG. 6). The semiconductive layer 21 may for example be precursor pentacene, spun from CH₂Cl₂ and subsequently converted for 10 seconds at 180° C. Other semiconductive materials may be used to form the semiconductive layer 21, such as for example organic materials (e.g. other polyacens, polyfluorens, polyphenylenevinylens) or mixtures being of unipolar or ambipolar nature [E. J. Meijer et al, Nature Materials 2, 678, 2003]. Alternatively, inorganic semiconductive materials (e.g. InP, GaAs, GaN, ZnS, CdS), provided the maximum process temperature for processing them is less than 200° C. may be used. Ideally, the workfunction of the semiconductive layer 21 and the second conductive layer should be matched such that an ohmic contact is formed between them. The semiconductive layer 21 may for example have a thickness of a few ten nm. The thickness of the semiconductive layer 21 may on one hand not be too small because in that case the layer may be discontinuous. On the other hand, the thickness may not be too high because then the device will show background current leakage. The semiconductive layer 21 does not require patterning. However, patterning may improve properties by reducing lateral leakage and is preferably performed. The semiconductive layer 21 determines the electrical switching behavior of the transistor 22, which may for example be a thin film transistor (TFT) as illustrated in FIG. 7.

In FIG. 7 a complete ferroelectric memory device 30 is illustrated, comprising a transistor 22, a capacitor 23 and a via 24. For the manufacturing of this ferroelectric memory device 30 according to the method described in the above embodiment of the present invention only three mask steps (or only two steps when the ferroelectric is not patterned) are required because the gate dielectric layer of the transistor 22 and the dielectric layer of the capacitor 23 are made from the same ferroelectric layer 14. Through this, processing time of the ferroelectric memory device 30 is shortened with respect to the method in the prior art and processing costs are decreased. The ferroelectric memory device 30 of the present invention is non-volatile, electrically re-programmable and voltage driven.

The ferroelectric characteristics of the capacitor 23 with organic ferroelectric dielectric layers are substantially independent of the materials, which are used to form both first electrodes 12 and second electrodes 18 of the capacitor 23. Preferably, an electrode material is used which does not show preferential binding to the ferroelectric layer 5 via for example hydrogen bonding interactions, such as for example PEDOT/PSS or Au, as they will have no influence on the switching characteristics of the devices formed. This is not the case for the inorganic counterparts and this often poses serious problems in structures, which use inorganic ferroelectric materials. The independence of the ferroelectric characteristics of the electrode material is related to observe low leakage currents in the capacitors 23 made according to embodiments of the method of the present invention.

A ferroelectric memory cell 30 according to an embodiment of the present invention is thus constructed such that the ferroelectric layer 14 is incorporated in the transistor 22 as the insulator dielectric. The memory in the device is within the ferroelectric capacitor 23. This is the non-volatile part in which remnant charge is stored by means of bistable ferroelectric polarization. The programming and reading will be done using the transistor preferably without switching it. In this embodiment this transistor does not need to be bistable. Within the cell, the SD voltage must be used to generate the switching voltage over the ferroelectric cell 23. The gate voltage just turns the channel on and off. Thus, reading is destructive in this device. The switching speed is in first approximation determined by the RC time constant defined by channel conductance of the transistor and capacitance of the ferroelectric capacitor.

Furthermore, the gate capacitance of the transistor 22 invokes a depolarization field within the storage capacitor 23. In order to keep this depolarization field lower than the coercive field, i.e. the field at which switching of the storage capacitor 23 takes place, the ferroelectric capacitor 23 feature size should roughly be smaller than ⅕^{th} of the transistor 22 feature size, in case of VDF ferroelectric polymers, i.e. the capacitance of the storage capacitor 23 should be approximately 20 times smaller than the transistor 22 gate capacitance. This ratio is dependent on the dielectric constant, the remnant polarization and the coercive field of the ferroelectric 14 and sets limits to the area ratio.

From FIGS. 6 and 7 it can be seen that the capacitor 23 is coupled in series with the drain 19 region of the transistor 22. In another embodiment, not represented in the drawings, the capacitor may be connected to the gate of the transistor. This construction is analogous to a ferroelectric transistor. In the 1T-1C cell where the capacitor is in series with the source drain channel, reading must be performed during switching. Then the Boolean 0 or 1 has to be deduced from a difference of charge defined by the two polarization states within the capacitor. I.e. at max, twice the remanent polarization and associated charge is available for detection of the memory state. If however, the charge of this capacitor is used to modulate the channel conductance of a transistor as is the case for a device where the capacitor is in series with the gate electrode, then the time multiplied with the source drain current determines the accuracy with which a state can be read. This situation provides more sensitivity, i.e. sensitivity can be pre-chosen by the reading time. Furthermore, when the capacitor 23 is in series with the gate electrode 13, reading of the memory state is done using the level of source-drain current without altering the ferroelectric capacitor state. Hence, it is non-destructive. In that case, the process can also be performed by using only 3 mask steps.

In a specific example of the above embodiment of the present invention the manufacturing of a ferroelectric memory device 30 is detailed, wherein the first and the second conductive layers are PEDOT/PSS layers and wherein the ferroelectric layer 14 is a ferroelectric polymer layer such as a VDF/TrFE layer.

The process steps of the manufacturing of the memory element of this example may be as follows. A first conductive PEDOT/PSS layer is deposited onto the substrate 10 according to the following method. A composition of the PEDOT/PSS salt in water is commercially available from Bayer as Baytron P. The concentration of PEDOT in this composition is 0.5% by weight and that of PSS is 0.8% by weight. To the composition, apparently a colloidal solution about 0.25% by weight is added. This colloidal solution may comprise an initiator, which initiates crosslinking after exposure with suitable light, and which may for example be 4,4′diazidodibenzalacetone-2,2′-disulphonic acid disodium salt and 0.005% by weight of dodecylbenzenesulphonic acid sodium salt, which is a kind of soap, surface tension reducer or wetting agent to enhance the wetting properties. After filtration through a filter preferably having pores with a diameter of 5 micron or less, the composition is spincoated onto the (optionally planarized) substrate 10. The layer thus obtained is dried for example at 30° C. for 5 minutes. The dried layer is then exposed through a mask to radiation with UV light (e.g. with a wavelength X of 365 nm) by means of for example a Hg lamp. Subsequently, the layer is washed by spraying with water. In this washing step, the non-irradiated areas of the layer are dissolved. After drying at 200° C., the average layer thickness of the remaining areas of the PEDOT/PSS layer is 80 nm. These areas have an electrical conductivity of 1 S/cm. Each continuous undissolved area functions as a conductive area such as for example a first interconnect line, a first electrode of the capacitor or a gate electrode of the transistor.

Subsequently a film of, for example, a random copolymer (CH₂—CF₂)ₙ—CEF—CF₂)ₘ wherein for example n=m (however, other m/n ratios may be used as well) is spincoated onto the PEDOT/PSS layer using a filtered (0.2 μm disposable) 5 weight percent solution of (CH₂—CF₂)ₙ—CHF—CF₂)ₘ random copolymer in VLSI grade 2-butanon and spinning for 10 seconds at 2000 rpm followed by 25 seconds at 250 rpm. This results in a layer with a thickness of approximately 400 nm, which has a highly hydrophobic water resistant surface.

To deposit a second PEDOT/PSS layer onto the VDF/TrFE layer the same method is used as for deposition of the first PEDOT/PSS layer. However, modification of the spincoating solution is necessary, because spincoating of the second PEDOT/PSS layer from a watery solution results in severe dewetting. This may be overcome by improving the wettability properties of the spincoating solution through addition of a surface tension reducing solvent, such as for example n-butanol, or by addition of a soap-like reagent. Therefore, in this specific embodiment of the present invention, the second PEDOT/PSS layer is deposited on top of the VDF/TrFE layer by the same method as in case of the first PEDOT/PSS layer, except for the fact that now 4% n-butanol is added to the spincoating solution. After applying the standard patterning procedure to the second PEDOT/PSS layer, the conductivity of the layer is raised by spincoating 5% diethyleneglycol in water on top and heating e.g. to 110° C. for 45 min. Next, annealing at 140° C. for 2 hours in vacuum is conducted to increase crystallinity of the VDF layer. The hysteresis loop of a square 1 mm² capacitor recorded at 1 Hz before and after annealing is shown in FIG. 8. It has been found that reducing the thickness of the VDF/TrFE layer leads to decreased switching voltages V_{c}. Layers of for example 250 nm lead to switching voltages of about 25 V while layers of 150 nm lead to switching voltages of about 15 V. In all cases the same remnant polarization (Pᵣ) is obtained.

In a last step a semiconductor layer is added according to conventional deposition techniques known by a person skilled in the art in order to complete the transistor. Hysteresis loops on capacitors were measured again before and after annealing. No significant differences were found.

It is to be understood that although preferred embodiments, specific constructions and configurations, as well as materials, have been discussed herein for devices according to the present invention, various changes or modifications in form and detail may be made without departing from the scope and spirit of this invention. For example, many different combinations of first and second conductive layers may be used for combination with a ferroelectric layer.

The present invention relates to non-volatile ferroelectric memory devices 30 comprising a transistor 22 and a capacitor, and more particularly to non-volatile electrically erasable programmable ferroelectric memory elements, and a method for processing such non-volatile ferroelectric memory devices. The method according to the invention comprises a limited number of mask steps because a gate dielectric layer of the transistor 22 and a dielectric layer of the capacitor 23 are made from the same organic or inorganic ferroelectric layer.

1. A device applicable for non-volatile memory purposes or latch-up circuits, the device comprising:
a selection device having a control electrode and a first dielectric layer insulating the control electrode from the rest of the selection device, and
a storage device comprising a second dielectric layer,
wherein the first dielectric layer of the selection device and the second dielectric layer of the storage device are individual parts of one and the same ferroelectric layer.

2. A device according to claim 1, wherein the selection device is a transistor comprising a gate electrode a gate dielectric and a drain and a source and wherein the storage device is a capacitor comprising a first electrode, a dielectric layer and a second electrode wherein the gate dielectric of the transistor and the dielectric layer of the capacitor are individual parts of one and the same ferroelectric layer.

3. The device according to claim 1, wherein the gate electrode of the transistor and the first electrode of the capacitor are individual parts of a first conductive layer.

4. The device according claim 1, wherein the drain and source of the transistor and the second electrode of the capacitor are individual parts of a second conductive layer.

5. The device according to claim 1, wherein one of the first and second electrode of the capacitor is electrically connected to drain the source or the gate of the transistor.

6. The device according to claim 1, wherein the gate electrode, the drain and the source of the transistor and the first electrode and the second electrode of the capacitor are formed of PEDOT/PSS.

7. The device according to claim 1, the device furthermore comprising a semiconductive layer.

8. The device according to claim 7, wherein the semiconductive layer is an organic semiconductive layer.

9. The device according to claim 1, wherein the ferroelectric layer comprises a hole.

10. A method for processing device applicable for non-volatile memory purposes or latch-up circuits comprising a selection device comprising a control electrode, a first dielectric layer and a first and second main electrode, and a storage device comprising a first electrode a second dielectric layer and a second electrode the method comprising:
providing and patterning of a first conductive layer onto a substrate thus forming the first electrode of the storage device and the control electrode of the selection device,
providing and patterning of a ferroelectric layer on the patterned first conductive layer, thus forming the first dielectric layer of the selection device and the second dielectric layer of the storage device and
providing and patterning of a second conductive layer on the patterned ferroelectric layer thus forming the second electrode of the capacitor and the first and second main electrode of the selection device.

11. The method according to claim 10, wherein providing of the ferroelectric layer is providing of a ferroelectric polymer layer.

12. The method according to claim 10, wherein patterning the ferroelectric layer comprises crosslinking the ferroelectric layer.
